(19) United States
(12) Patent Application Publication
(10) Pub. No.: US 2022/0268568 A1
(43) Pub. Date: Aug. 25, 2022

(54) THICKNESS MEASUREMENT DEVICE

(71) Applicant: IUCF-HYU (INDUSTRY-UNIVERSITY COOPERATION FOUNDATION HANYANG UNIVERSITY), Seoul (KR)

(72) Inventors: Hak Sung KIM, Seoul (KR); Dong Woon PARK, Seoul (KR); Gyung Hwan OH, Seoul (KR); Heon Su KIM, Seoul (KR)

(73) Assignee: INDUSTRY-UNIVERSITY COOPERATION FOUNDATION HANYANG UNIVERSITY, Seoul (KR)

(21) Appl. No.: 17/629,163

(22) PCT Filed: Jul. 20, 2020
(86) PCT No.: PCT/KR2020/009536

§ 371 Date: Jan. 21, 2022

(30) Foreign Application Priority Data
Jul. 24, 2019 (KR) 10-2019-0089442

(51) Int. Cl. G01B 11/06; G06F 17/14

(52) U.S. Cl. CPC G01B 11/06; G06F 17/142

(57) ABSTRACT

According to an aspect of the invention, a thickness measuring device comprising: an emission unit emitting an electromagnetic wave toward a specimen, a reception unit receiving an electromagnetic wave output from a direction in which the specimen is positioned; and a control unit calculating a thickness of the specimen by receiving a signal from the reception unit, wherein when the specimen has a first thickness, the reception unit receives a first electromagnetic wave, and when the specimen has a second thickness, the reception unit receives a second electromagnetic wave, wherein the first electromagnetic wave has a first peak value at a first time point, and the second electromagnetic wave has a second peak value at a second time point, and wherein when the first thickness is greater than the second thickness, the first peak value is smaller than the second peak value, may be provided.

### TECHNICAL FIELD

The present invention relates to a thickness measurement device that is a device which measures a thickness of a specimen using electromagnetic waves.

### BACKGROUND ART

With the development of cutting-edge industries such as the semiconductor and display industries, high-density and miniaturization technologies are currently in the spotlight, and the development of non-destructive inspection technologies is also required.

Particularly, in the semiconductor and display industries, specimens that are used for small precision components and have various thicknesses and shapes are manufactured. The specimens may correspond to thin films. Since the specimens greatly affect the performance of products, there is a need to manufacture the specimens with uniform thicknesses. Accordingly, it is necessary to precisely measure the thickness of such specimens while the specimens are manufactured.

### Technical Problem

The present invention is directed to providing a thickness measurement system which measures a thickness of a specimen using electromagnetic waves.

The present invention is directed to providing a thickness measurement device which measures a thickness of a specimen using electromagnetic waves.

The present invention is directed to providing a thickness measurement device which compares thicknesses of specimens using peak points of electromagnetic waves measured using the electromagnetic waves.

The present invention is directed to providing a thickness measurement device which calculates a thickness of a specimen by applying a fast Fourier transform (FFT) algorithm to electromagnetic waves reflected by a specimen in the frequency domain.

The present invention is directed to providing a thickness measurement device which calculates a thickness of a specimen by calculating a complex relative refractive index and an extinction coefficient from electromagnetic waves reflected by the specimen in the frequency domain.

The present invention is directed to providing a thickness measurement device which calculates a complex relative refractive index and an extinction coefficient from electromagnetic waves reflected by a specimen in the frequency domain to calculate a thickness of the specimen on the basis of a prestored function.

The present invention is directed to providing a thickness measurement device which calculates a thickness of a specimen using a prestored function and in which the function is correctable using calculated thickness information of the specimen.

Objectives to be solved by the present invention are not limited to the above-described objectives, and objectives which are not described above will be clearly understood by those skilled in the art through the present specification and the accompanying drawings.

### Technical Solution

According to an aspect of the invention, a thickness measuring device comprising: an emission unit emitting an electromagnetic wave toward a specimen, a reception unit receiving an electromagnetic wave output from a direction in which the specimen is positioned; and a control unit calculating a thickness of the specimen by receiving a signal from the reception unit, wherein when the specimen has a first thickness, the reception unit receives a first electromagnetic wave, and when the specimen has a second thickness, the reception unit receives a second electromagnetic wave, wherein the first electromagnetic wave has a first peak value at a first time point, and the second electromagnetic wave has a second peak value at a second time point, and wherein when the first thickness is greater than the second thickness, the first peak value is smaller than the second peak value, may be provided.

### Advantageous Effects

According to embodiments, since a thickness measuring device can measure a thickness of a specimen by emitting electromagnetic waves to the specimen, there is an effect of performing a non-destructive inspection on the specimen. When the electromagnetic waves are terahertz waves, since the electromagnetic waves have a higher transmittance than visible or infrared light, there are effects in that the thickness measuring device can be used in a place where external light is present, and the thickness of the specimen can be measured even without performing an additional process of blocking external light.

Since the thickness measurement device can compare thicknesses of specimens on the basis of peak values of electromagnetic waves reflected by the specimens and time points at which peaks occur, the thicknesses of a plurality of specimens can be easily compared in a short time, and thus a time for measuring the thickness of the specimen can be reduced.

Since the thickness measurement device can emit electromagnetic waves toward a specimen and calculate a complex relative refractive index and an extinction coefficient from the electromagnetic waves reflected by the specimen in the frequency domain to measure a thickness of the specimen on the basis of a prestored function, there is an effect of improving accuracy of the calculated thickness of the specimen.

In addition, in the thickness measurement device, since the prestored function can be corrected whenever the thickness measurement device calculates a thickness of a specimen, there is an effect of improving accuracy whenever the thickness of the specimen is measured.

Accordingly, the thickness measurement device can measure a thickness of a specimen in a non-contact manner and a non-destructive manner. In addition, since accuracy can be improved when compared to a case in which a thickness is calculated on the basis of a difference in time between electromagnetic waves which are reflected by a specimen or pass through the specimen, there is an effect of high usability.

Effects of the present invention are not limited to the above-described effects, and effects which are not described above will be clearly understood by those skilled in the art through the following specification and the accompanying drawings.

### DESCRIPTION OF DRAWINGS

FIG. 1 is a view illustrating a thickness measurement system according to one embodiment.

FIG. 2 is a block diagram illustrating a control unit, an emission unit, and a reception unit of a thickness measurement device according to one embodiment.

FIG. 3 is a block diagram illustrating a configuration of the control unit of the thickness measurement device according to one embodiment.

FIGS. 4 and 5 are views illustrating electromagnetic waves reflected by a specimen in the thickness measurement device according to one embodiment.

FIG. 6 is a graph showing electromagnetic waves received by the reception unit of the thickness measurement device according to one embodiment over time.

FIGS. 7 and 8 are graphs showing a complex relative refractive index calculated by applying a fast Fourier transform (FFT) algorithm to electromagnetic waves received by the reception unit of the thickness measurement device according to one embodiment over frequency.

FIGS. 9 and 10 are graphs showing an extinction coefficient calculated by applying the FFT algorithm to electromagnetic waves received by the reception unit of the thickness measurement device according to one embodiment over frequency.

### BEST MODES OF THE INVENTION

Hereinafter, specific embodiments of the present invention will be described in detail with reference to the accompanying drawings. However, the scope of the present invention is not limited to the suggested embodiments, and other embodiments which are included in retrograde inventions or in the scope of the present invention may be easily suggested by those skilled in the art by adding, modifying, and deleting other components in the same scope of the present invention, and this may also be within the scope of the present invention.

In addition, components which are illustrated in drawings for embodiments and have the same function in the same scope are assigned and described with the same reference numerals.

According to an aspect of the invention, a thickness measuring device comprising: an emission unit emitting an electromagnetic wave toward a specimen, a reception unit receiving an electromagnetic wave output from a direction in which the specimen is positioned; and a control unit calculating a thickness of the specimen by receiving a signal from the reception unit, wherein when the specimen has a first thickness, the reception unit receives a first electromagnetic wave, and when the specimen has a second thickness, the reception unit receives a second electromagnetic wave, wherein the first electromagnetic wave has a first peak value at a first time point, and the second electromagnetic wave has a second peak value at a second time point, and wherein when the first thickness is greater than the second thickness, the first peak value is smaller than the second peak value, may be provided.

Also, thickness measuring device, wherein the first time point is a time point which is faster than the second time point, may be provided.

Also, thickness measuring device, wherein the first thickness is in inversely proportional to the first time point and the first peak value may be provided.

Also, thickness measuring device, wherein the control unit includes a complex relative refractive index calculation unit calculating complex relative refractive index of the specimen using FFT (Fast Fourier Transform) algorithm to the first electromagnetic wave and the second electromagnetic wave and an extinction coefficient calculation unit calculating extinction coefficient of the specimen, may be provided.

Also, thickness measuring device, wherein the control unit includes a function storage unit for storing functions for the complex relative refractive index and extinction coefficient with respect to the thickness of the specimen in the frequency domain in advance, and a thickness calculation unit for calculating a thickness of the specimen based on a value calculated by the complex relative refractive index calculation unit and the extinction coefficient calculation unit and a value stored at the function storage unit, may be provided.

Also, thickness measuring device, wherein the control unit includes a data storage unit for storing a data output from the thickness calculation unit, and wherein the data stored in the data storage unit is transferred to the function storage unit so that a function stored in the function storage unit can be modified, may be provided.

Also, thickness measuring device, wherein when the first thickness is greater than the second thickness, the complex relative refractive index of the first electromagnetic wave is smaller than the complex relative refractive index of the second electromagnetic wave may be provided.

Also, thickness measuring device, wherein when the first thickness is greater than the second thickness, the extinction coefficient of the first electromagnetic wave is greater than the extinction coefficient of the second electromagnetic wave, may be provided.

Also, thickness measuring device, wherein when the frequency increases, the complex relative refractive index of the first electromagnetic wave also increases, may be provided.

Also, thickness measuring device, wherein the first electromagnetic wave has a first complex relative refractive index at a first frequency and a second complex relative refractive index at a second frequency, wherein the first electromagnetic wave has a first slope with respect to the first complex relative refractive index at the first frequency, and a second slope with respect to the second complex relative refractive index at the second frequency, and wherein when the first frequency is less than the second frequency, the first slope is greater than the second slope, may be provided.

Also, thickness measuring device, wherein when the frequency increases, the extinction coefficient of the first electromagnetic wave decreases, may be provided.

Also, thickness measuring device, wherein the first electromagnetic wave has a first extinction coefficient at a first frequency and a second extinction coefficient at a second frequency, wherein the first electromagnetic wave has a first slope with respect to the first extinction coefficient at the first frequency, and a second slope with respect to the second extinction coefficient at the second frequency, and wherein when the first frequency is less than the second frequency, an absolute value of the first slope is greater than an absolute value of the second slope, may be provided.

Also, thickness measuring device, wherein the first electromagnetic wave and the second electromagnetic wave are terahertz waves, may be provided.

### MODES OF THE INVENTION

Hereinafter, a thickness measurement device according to one embodiment of the present invention will be described.

A thickness measurement system according to one embodiment of the present invention will be described.

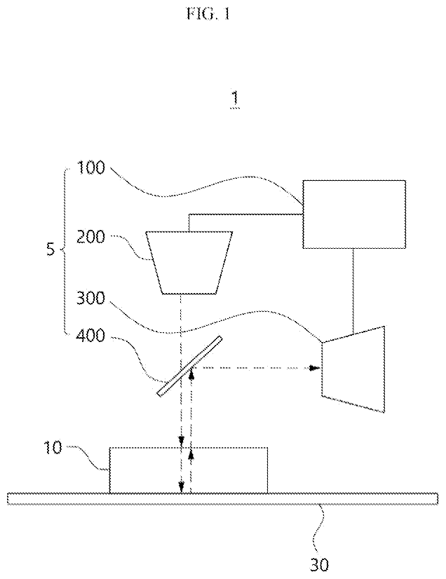

FIG. 1 is a view illustrating the thickness measurement system according to one embodiment.

Referring to FIG. 1, a thickness measurement system 1 may include a thickness measurement device 5, a specimen 10, and a supporter 30.

The thickness measurement system 1 is a system for measuring a thickness of the specimen 10. The thickness measurement system 1 may measure the thickness of the specimen 10 disposed on the supporter 30.

The thickness measurement device 5 may include a control unit 100, an emission unit 200, a reception unit 300, and a beam splitter 400.

In the thickness measurement device 5, the emission unit 200 may emit electromagnetic waves to measure the thickness of the specimen 10 supported by the supporter 30 according to control of the control unit 100. In the thickness measurement device 5, the reception unit 300 may receive electromagnetic waves that are reflected by the specimen 10 and pass through the beam splitter 400 to measure the thickness of the specimen 10. The thickness measurement device 5 may measure the thickness of the specimen 10 on the basis of the electromagnetic waves reflected by the specimen 10.

A compound deposited on the specimen 10 may be silicon nitride or another material. The specimen 10 may have a predetermined thickness. The compound deposited on the specimen 10 may have a predetermined thickness.

The specimen 10 may correspond to a thin film. The specimen 10 may be silicon nitride or another material deposited on a silicon wafer.

The specimen 10 may be a first specimen having a first thickness d1. The specimen 10 may be a second specimen having a second thickness d2.

The first specimen may be the same as or different from the second specimen. The first thickness d1 may be the same as or different from the second thickness d2.

At least one region of the specimen 10 may be in contact with the supporter 30. The specimen 10 may be fixed to the supporter 30 or placed thereon without being fixed thereto.

The supporter 30 may serve to support the specimen 10. The supporter 30 may be formed of a material capable of reflecting or transmitting electromagnetic waves emitted by the emission unit 200. When at least some of the electromagnetic waves emitted by the emission unit 200 pass through the specimen 10 and arrive at the supporter 30, the supporter 30 may reflect or transmit at least some of the electromagnetic waves that have passed through the specimen 10.

The control unit 100 may allow the emission unit 200 to emit electromagnetic waves toward the specimen 10 to calculate the thickness of the specimen 10.

When at least some of the electromagnetic waves emitted by the emission unit 200 arrive at a surface of the specimen 10 according to control of the control unit 100, the specimen 10 may reflect or transmit at least some of the electromagnetic waves arriving at the surface of the specimen 10.

When the at least some of the electromagnetic waves emitted by the emission unit 200 arrive at a rear surface of the specimen 10 according to control of the control unit 100, the specimen 10 may reflect or transmit the at least some of the electromagnetic waves arriving at the rear surface of the specimen 10.

The control unit 100 may allow the reception unit 300 to receive electromagnetic waves output from the specimen 10 and recognize the received waves. The control unit 100 may calculate the thickness of the specimen 10 on the basis of the waves received by the reception unit 300.

The control unit 100 may calculate the thickness of the specimen 10 on the basis of the waves received by the reception unit 300. The control unit 100 may calculate the thickness of the specimen 10 on the basis of peak occurrence time points and peak values of electromagnetic waves included in a predetermined time interval among the waves received by the reception unit 300.

The control unit 100 may detect the peak values and the peak occurrence time points of the electromagnetic waves received by the reception unit 300. The control unit 100 may calculate the thickness of the specimen 10 on the basis of the peak occurrence time points of the electromagnetic waves received by the reception unit 300.

The control unit 100 may calculate a complex relative refractive index and an extinction coefficient of electromagnetic waves received by the reception unit 300 by applying a fast Fourier transform (FFT) algorithm to the electromagnetic waves.

The control unit 100 may store a function for the complex relative refractive index and the thickness of the specimen in advance. The control unit 100 may store a function for the extinction coefficient and the thickness of the specimen in advance.

The control unit 100 may calculate the thickness of the specimen 10 on the basis of the complex relative refractive index of the electromagnetic waves received by the reception unit 300 and the prestored complex relative refractive index-thickness function.

The control unit 100 may calculate the thickness of the specimen 10 on the basis of the extinction coefficient of the electromagnetic waves received by the reception unit 300 and the prestored extinction coefficient-thickness function.

The emission unit 200 may be positioned above the specimen 10. The emission unit 200 may be positioned apart from the specimen 10 in a vertical direction. The emission unit 200 may be directed toward the specimen 10.

The emission unit 200 may emit electromagnetic waves. The emission unit 200 may emit terahertz waves. A wavelength of the electromagnetic waves emitted by the emission unit 200 may be in the range of 30 μm to 3 mm. The electromagnetic waves may be continuous or pulse waves. One or more light sources of the electromagnetic waves may be provided. A frequency of the electromagnetic waves may be in the range of 0.1 THz to 10 THz. Since the emission unit 200 may emit the electromagnetic waves in the frequency range, the electromagnetic waves may have a higher transmittance than visible light or infrared light.

In addition, since the electromagnetic waves emitted by the emission unit 200 may be used in a place where external light is present, the thickness of the specimen 10 may be measured even without performing an additional process of blocking external light. Since the electromagnetic waves emitted by the emission unit 200 have the higher transmittance, the electromagnetic waves may be reflected by or may pass through the surface of the specimen 10 and may arrive at the rear surface of the specimen 10 in at least a region of the specimen 10.

The reception unit 300 may receive the electromagnetic waves reflected by the specimen 10. The reception unit 300 may be positioned apart from the beam splitter 400. The reception unit 300 may be positioned on a path along which the electromagnetic waves reflected by the specimen 10 are reflected by the beam splitter 400. A direction from the beam splitter 400 toward the emission unit 200 may be perpendicular to a direction from the beam splitter 400 toward the reception unit 300.

The reception unit 300 may receive different electromagnetic waves according to thicknesses of specimens 10.

The reception unit 300 may receive first electromagnetic waves w1 which are emitted by the emission unit 200 and output after being reflected by the first specimen having the first thickness d1. The reception unit 300 may receive second electromagnetic waves w2 which are emitted by the emission unit 200 and output after being reflected by the second specimen having the second thickness d2.

The beam splitter 400 may be positioned between the emission unit 200 and the specimen 10. The beam splitter 400 may be positioned on a path of electromagnetic waves emitted in a direction from the emission unit 200 toward the specimen 10.

The beam splitter 400 may reflect or transmit some light incident thereon. The beam splitter 400 may transmit some light emitted by the emission unit 200, the transmitted light may be reflected by the specimen 10 on the supporter 30, and some of the reflected light may be reflected by the beam splitter 400 and received by the reception unit 300.

An optical path in the thickness measurement system 1 according to one embodiment of the present invention will be described below.

The emission unit 200 may emit electromagnetic waves toward the specimen 10 according to control of the control unit 100. The electromagnetic waves emitted by the emission unit 200 may arrive at the beam splitter 400. At least some of the electromagnetic waves which have arrived at the beam splitter 400 may arrive at the surface of the specimen 10.

At least some of the electromagnetic waves which have arrived at the surface of the specimen 10 are reflected by the surface of the specimen 10. At least some of the electromagnetic waves which have arrived at the surface of the specimen 10 pass through the surface and arrive at the rear surface of the specimen 10. At least some of the light which has arrived at the rear surface of the specimen 10 is reflected by the rear surface of the specimen 10.

The electromagnetic waves reflected by the surface and the rear surface of the specimen 10 may arrive at the beam splitter 400. At least some of each of the electromagnetic waves which have arrived at the beam splitter 400 may arrive at the reception unit 300.

The reception unit 300 may receive the electromagnetic waves reflected by the surface of the specimen 10. The reception unit 300 may receive the electromagnetic waves reflected by the rear surface of the specimen 10.

The above-described optical paths of the electromagnetic waves are one example of the present invention, and in the present invention, optical paths of electromagnetic waves are not limited thereto. Optical paths of electromagnetic waves may vary according to a layout of a structure of the thickness measurement device 5.

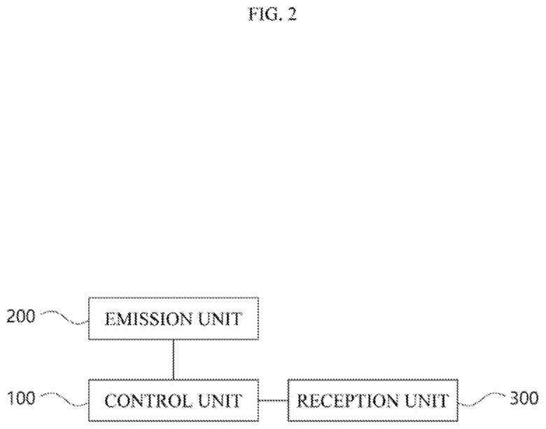

FIG. 2 is a block diagram illustrating the control unit, the emission unit, and the reception unit of the thickness measurement device according to one embodiment.

Referring to FIG. 2, the thickness measurement device 5 according to one embodiment includes the control unit 100, the emission unit 200, and the reception unit 300.

The control unit 100 may control both of the emission unit 200 and the reception unit 300.

The emission unit 200 may be operated according to a signal of the control unit 100. The emission unit 200 may emit electromagnetic waves toward the specimen 30 according to a signal of the control unit 100.

The reception unit 300 may be operated according to a signal of the control unit 100. The reception unit 300 may receive electromagnetic waves output from the specimen 10 according to a signal of the control unit 100.

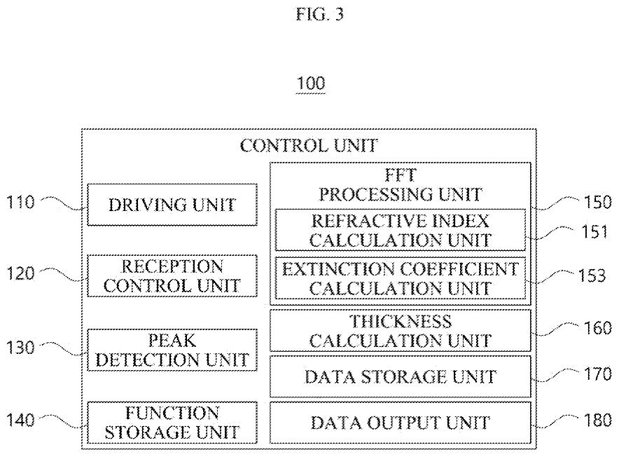

FIG. 3 is a block diagram illustrating a configuration of the control unit of the thickness measurement device according to one embodiment.

Referring to FIG. 3, the control unit 100 of the thickness measurement device 5 according to one embodiment may include a driving unit 110, a reception control unit 120, a peak detection unit 130, a function storage unit 140, an FFT processing unit 150, a thickness calculation unit 160, a data storage unit 170, and a data output unit 180.

The FFT processing unit 150 may include a complex relative refractive index calculation unit 151 and an extinction coefficient calculation unit 153.

The driving unit 110 may control the emission unit 200 to emit electromagnetic waves. The driving unit 110 may control the emission unit 200 to emit the electromagnetic waves when the specimen 10 is positioned at a position corresponding to the emission unit 200. The driving unit 110 may control the emission unit 200 to emit the electromagnetic waves when a thickness measurement region of the specimen 10 is positioned at a position corresponding to the emission unit 200.

The reception control unit 120 may control the reception unit 300 to receive electromagnetic waves. The reception unit 300 may receive the electromagnetic waves according to control of the reception control unit 120. The reception unit 300 may transmit a result of the received waves to the reception control unit 120. The reception control unit 120 may control the reception unit 300 to transmit the result of the received waves. The reception control unit 120 may transmit the result of the received waves to the FFT processing unit 150.

The peak detection unit 130 may detect a peak value and a peak occurrence time point of the electromagnetic waves received by the reception unit 300. The peak detection unit 130 may detect a peak value and a peak occurrence time point of each of a plurality of electromagnetic waves received by the reception unit 300. The peak detection unit 130 may detect the peak value and the peak occurrence time point of the electromagnetic waves and transmit a result thereof to the thickness calculation unit 160 and the data storage unit 180.

The function storage unit 140 may store a function for a correlation between a complex relative refractive index and a thickness of the specimen in the frequency domain in advance. The function storage unit 140 may store a function for a correlation between an extinction coefficient and a thickness of the specimen in the frequency domain in advance.

The function which is stored in the function storage unit 140 and related to complex relative refractive index-thickness may be obtained at a specific frequency. When the function related to the complex relative refractive index-thickness is obtained at a frequency in which a magnitude of electromagnetic waves is 45 dB or more, accuracy may be improved.

The function which is stored in the function storage unit 140 and related to extinction coefficient-thickness may be obtained in a specific frequency. When the function related to the extinction coefficient-thickness is obtained at a frequency in which a magnitude of electromagnetic waves is 45 dB or more, accuracy may be improved.

The FFT processing unit 150 may receive a result of waves received by the reception control unit 120 from the reception unit 300. The FFT processing unit 150 may convert the result received from the reception control unit 120 from the time domain to the frequency domain using an FFT algorithm.

The FFT processing unit 150 may include the complex relative refractive index calculation unit 151 capable of calculating a complex relative refractive index from electromagnetic waves in the frequency domain. The FFT processing unit 150 may include the extinction coefficient calculation unit 151 capable of calculating an extinction coefficient from electromagnetic waves in the frequency domain.

The complex relative refractive index calculation unit 151 may calculate a complex relative refractive index of electromagnetic waves. The complex relative refractive index calculation unit 151 may calculate a relationship of a complex relative refractive index according to a frequency.

The extinction coefficient calculation unit 153 may calculate an extinction coefficient of electromagnetic waves. The extinction coefficient calculation unit 153 may calculate a relationship of an extinction coefficient according to a frequency.

The complex relative refractive index calculation unit 151 and the extinction coefficient calculation unit 153 may transmit calculated results to the thickness calculation unit 160 and the function storage unit 140.

The thickness calculation unit 160 may calculate a thickness of the specimen 10. The thickness calculation unit 160 may calculate the thickness of the specimen 10 using the results transmitted from the peak detection unit 130 and the FFT processing unit 150.

The thickness calculation unit 160 may calculate the thickness of the specimen 10 on the basis of a peak value and a peak occurrence time point of electromagnetic waves detected by the peak detection unit 130.

The thickness calculation unit 160 may calculate the thickness of the specimen 10 on the basis of a complex relative refractive index of electromagnetic waves calculated by the complex relative refractive index calculation unit 151. The thickness calculation unit 160 may calculate the thickness of the specimen 10 on the basis of the complex relative refractive index-thickness function, which is predetermined in the function storage unit 140, of the specimen 10.

The thickness calculation unit 160 may calculate the thickness of the specimen 10 on the basis of an extinction coefficient of electromagnetic waves calculated by the extinction coefficient calculation unit 153. The thickness calculation unit 160 may calculate the thickness of the specimen 10 on the basis of the extinction coefficient-thickness function, which is predetermined in the function storage unit 140, of the specimen 10.

The thickness calculation unit 160 may transmit a calculated result value to the data storage unit 180. The thickness calculation unit 160 may transmit the calculated result value to the function storage unit 140.

The function storage unit 140 may correct the prestored complex relative refractive index-thickness function and the prestored extinction coefficient-thickness function on the basis of results transmitted from the FFT processing unit 150 and the thickness calculation unit 160. Accordingly, the functions stored in the function storage unit 140 in advance may be corrected by the FFT processing unit 150 and the thickness calculation unit 160.

The data storage unit 180 may store data about the peak value and the peak occurrence time point of the electromagnetic waves detected by the peak detection unit 130. The data storage unit 180 may store data about the thickness of the specimen 10 calculated by the thickness calculation unit 160.

The data output unit 180 may output the data about the thickness of the specimen 10 calculated by the thickness calculation unit 160.

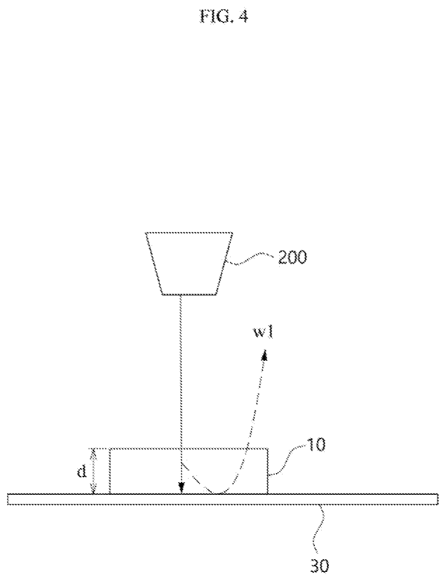

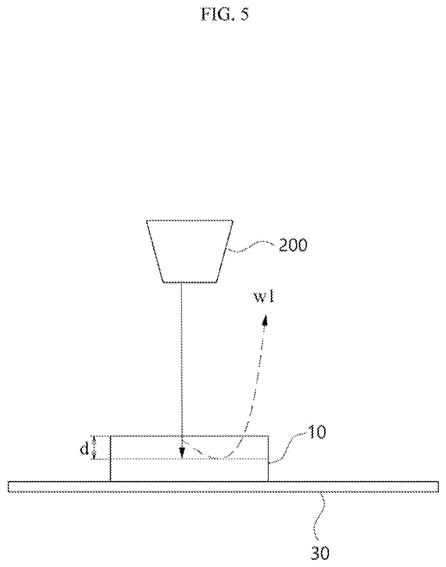

FIGS. 4 and 5 are views illustrating electromagnetic waves output after being reflected by the specimen in the thickness measurement device according to one embodiment.

FIG. 5 is a view illustrating electromagnetic waves output after being reflected by the specimen 10 when the specimen 10 is a thin film deposited on a silicon wafer.

Referring to FIG. 4, the specimen 10 may correspond to a target object. The emission unit 200 emits electromagnetic waves toward the specimen 10. The electromagnetic waves emitted by the emission unit 200 may be reflected by the specimen 10 or may pass through the specimen 10. The electromagnetic waves that pass through the surface of the specimen 10 and are reflected by the rear surface of the specimen 10 may be received by the reception unit 300 (not shown).

Referring to FIG. 5, the specimen 10 may correspond to a thin film deposited on a silicon wafer. The emission unit 200 emits electromagnetic waves toward the specimen 10. The electromagnetic waves emitted by the emission unit 200 may be reflected by the surface of the specimen 10 or may pass through the surface of the specimen 10. The electromagnetic waves emitted by the emission unit 200 may pass through the surface of the specimen 10 and may be reflected by an interface between the rear surface of the specimen 10 and a surface of the silicon wafer. The electromagnetic waves reflected by the interface between the rear surface of the specimen 10 and the surface of the silicon wafer may be received by the reception unit 300 (not shown).

Referring to FIGS. 4 and 5, the emission unit 200 emits the electromagnetic waves toward the specimen 10. The electromagnetic waves emitted by the emission unit 200 may be reflected by the specimen 10 or may pass through the specimen 10. The electromagnetic waves that pass through the surface of the specimen 10 and are reflected by the rear surface of the specimen 10 may be received by the reception unit 300 (not shown).

When the specimen 10 has the first thickness d1, the emission unit 200 emits electromagnetic waves toward the first specimen having the first thickness d1. The electromagnetic waves reflected by the first specimen are output in the form of first electromagnetic waves w1. The first electromagnetic waves w1 may be received by the reception unit 300.

When the specimen 10 has the second thickness d2, the emission unit 200 emits electromagnetic waves toward the second specimen having the second thickness d2. The electromagnetic waves reflected by the second specimen are output in the form of second electromagnetic waves w2. The second electromagnetic waves w2 may be received by the reception unit 300.

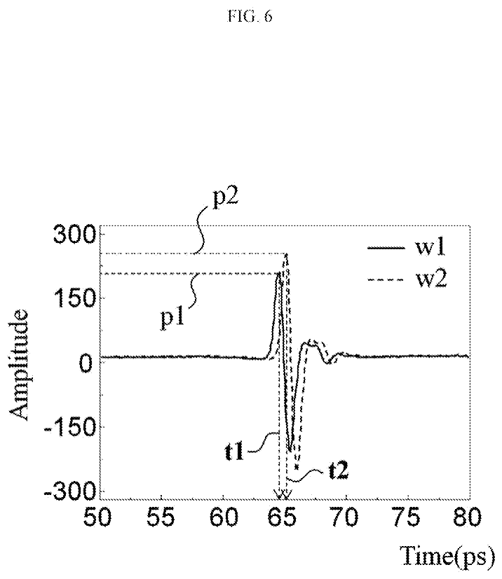

FIG. 6 is a graph showing electromagnetic waves received by the reception unit of the thickness measurement device according to one embodiment over time.

Referring to FIG. 6, the first electromagnetic waves w1 reflected by the first specimen having the first thickness d1 are received by the reception unit 300 according to control of the reception control unit 120 of the control unit 100.

The reception unit 300 may receive the first electromagnetic waves w1 reflected by the first specimen having the first thickness d1. The first electromagnetic waves w1 have a first peak value p1, and a time point at which the first peak value p1 occurs is a first time point t1. The first peak value p1 and the first time point t1 may be detected by the peak detection unit 130.

The reception unit 300 may receive the second electromagnetic waves w2 reflected by the second specimen having the second thickness d2. The second electromagnetic waves w2 have a second peak value p2, and a time point at which the second peak value p2 occurs is a second time point t2. The second peak value p2 and the second time point t2 may be detected by the peak detection unit 130.

When the thickness of the specimen 10 varies, the peak value and the peak occurrence time point of the electromagnetic waves received by the reception unit 300 may vary.

When the first thickness d1 is greater than the second thickness d2, the first peak value p1 may be smaller than the second peak value p2. In addition, the first time point t1 at which the first peak value p1 occurs may be earlier than the second time point t2 at which the second peak value p2 occurs.

The first thickness d1 may be inversely proportional to the first time point t1 and the first peak value p1. The second thickness d2 may be inversely proportional to the second time point t2 and the second peak value p2. The thickness of the specimen 10 may be inversely proportional to a peak value and a time point at which the peak value occurs of electromagnetic waves output after being reflected by the specimen 10.

The thickness measurement device 5 may compare the first thickness d1 of the first specimen and the second thickness d2 of the second specimen on the basis of the peak value and the peak occurrence time point of each of the first electromagnetic waves w1 and the second electromagnetic waves w2.

The thickness measurement device 5 may compare a thickness of a first region and a thickness of a second region on the basis of a peak value and a peak occurrence time point of each of electromagnetic waves output after being reflected by the first region of the specimen 10 and electromagnetic waves output after being reflected by the second region thereof. Accordingly, the thickness measurement device 5 may measure uniformity of the specimen 10.

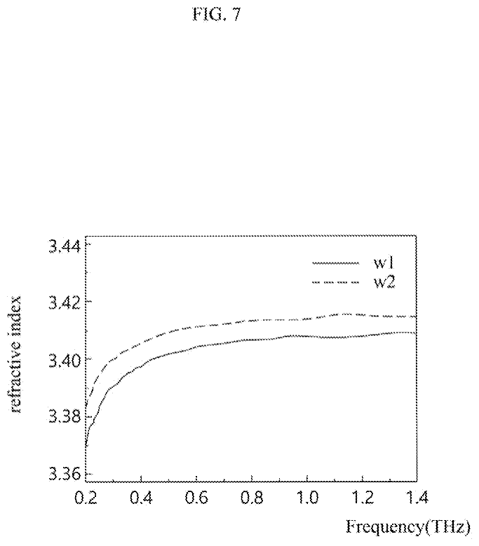

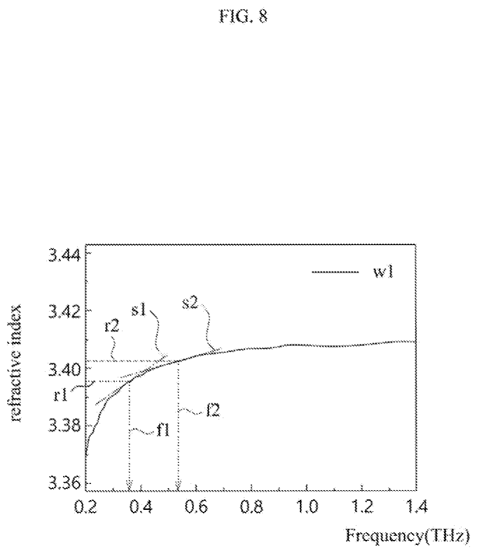

FIGS. 7 and 8 are graphs showing a complex relative refractive index calculated by applying the FFT algorithm to electromagnetic waves received by the reception unit of the thickness measurement device according to one embodiment over frequency.

FIG. 7 is a graph showing a complex relative refractive index of each of the first electromagnetic waves and the second electromagnetic waves over frequency. FIG. 8 is a graph showing the complex relative refractive index of the first electromagnetic waves over frequency.

Referring to FIG. 7, the first electromagnetic waves w1 are reflected by the first specimen having the first thickness d1 and received by the reception unit 300. The second electromagnetic waves w2 are reflected by the second specimen having the second thickness d2 and received by the reception unit 300.

When the first thickness d1 is greater than the second thickness d2, a complex relative refractive index of the first electromagnetic waves w1 may have a value greater than a value of a complex relative refractive index of the second electromagnetic waves w2 at any frequency.

The thickness measurement device 5 may compare the thickness of the first specimen and the thickness of the second specimen by comparing the complex relative refractive index of the first specimen and the complex relative refractive index of the second specimen.

Referring to FIG. 8, the first electromagnetic waves w1 are reflected by the first specimen having the first thickness d1 and received by the reception unit 300.

As a frequency increases, the value of the complex relative refractive index of the first electromagnetic waves w1 may increase. The complex relative refractive index of the first electromagnetic waves w1 may be proportional to the frequency.

The complex relative refractive index of the first electromagnetic waves w1 may have a positive first derivative with respect to the frequency. The complex relative refractive index of the first electromagnetic waves w1 may have a negative second derivative with respect to the frequency.

The first electromagnetic waves w1 may have a first complex relative refractive index r1 at a first frequency f1. The first electromagnetic waves w1 may have a first slope s1 which is an instantaneous slope with respect to the first complex relative refractive index r1 at the first frequency f1.

The first electromagnetic waves w1 may have a second complex relative refractive index r2 at a second frequency f2. The first electromagnetic waves w1 may have a second slope s2 which is an instantaneous slope with respect to the second complex relative refractive index r2 at the second frequency f2.

When the first frequency f1 is lower than the second frequency f2, a value of the first slope s1 may be greater than a value of the second slope s2. The complex relative refractive index of the first electromagnetic waves w1 may be proportional to the frequency, and an increase rate thereof may decrease in proportion to the frequency.

The complex relative refractive index calculation unit 151 may calculate the complex relative refractive index of each of the first electromagnetic waves w1 and the second electromagnetic waves w2 at a specific frequency. The thickness calculation unit 160 may calculate the thickness of the specimen 10 on the basis of a value calculated by the complex relative refractive index calculation unit 151 and the function prestored the function storage unit 140.

The complex relative refractive index-thickness function prestored in the function storage unit 140 may have a decreasing graph. At a specific frequency, the complex relative refractive index may be inversely proportional to the thickness of the specimen. At a specific frequency, as the complex relative refractive index increases, the thickness of the specimen may decrease.

A result value calculated by the complex relative refractive index calculation unit 151 and a result value calculated by the thickness calculation unit 160 may be transmitted to the function storage unit 140. The function storage unit 140 may correct the complex relative refractive index-thickness function on the basis of results received from the complex relative refractive index calculation unit 151 and the thickness calculation unit 160.

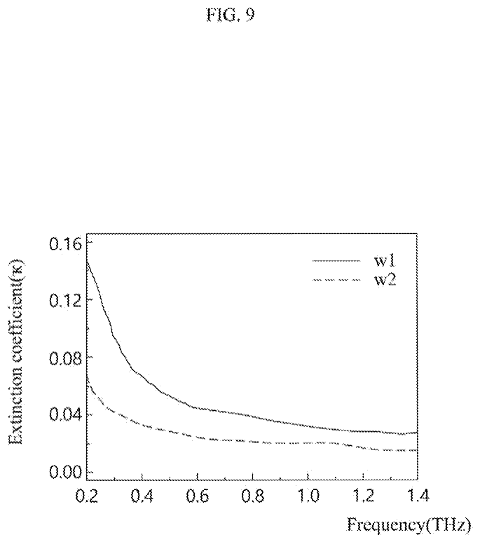

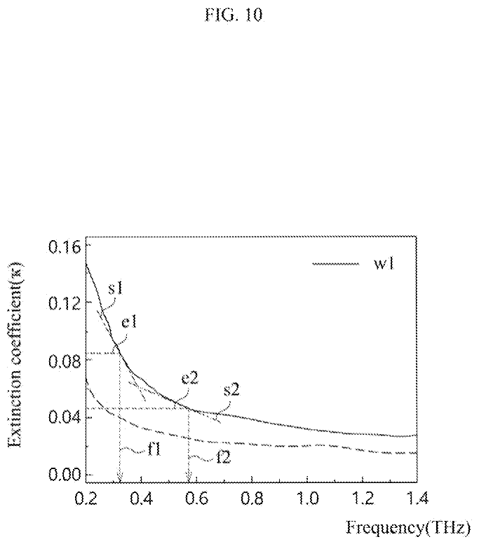

FIGS. 9 and 10 are graphs showing an extinction coefficient calculated by applying the FFT algorithm to electromagnetic waves received by the reception unit of the thickness measurement device according to one embodiment over frequency.

FIG. 9 is a graph showing an extinction coefficient of each of the first electromagnetic waves and the second electromagnetic waves over frequency. FIG. 10 is a graph showing the extinction coefficient of the first electromagnetic waves over frequency.

Referring to FIG. 9, the first electromagnetic waves w1 are reflected by the first specimen having the first thickness d1 and received by the reception unit 300. The second electromagnetic waves w2 are reflected by the second specimen having the second thickness d2 and received by the reception unit 300.

When the first thickness d1 is greater than the second thickness d2, a value of the extinction coefficient of the first electromagnetic waves w1 may be smaller than a value of the extinction coefficient of the second electromagnetic waves w2 at any frequency.

The thickness measurement device 5 may compare the thickness of the first specimen and the thickness of the second specimen by comparing the extinction coefficient of the first specimen and the extinction coefficient of the second specimen.

Referring to FIG. 10, the first electromagnetic waves w1 are reflected by the first specimen having the first thickness d1 and received by the reception unit 300.

As a frequency increases, the value of the extinction coefficient of the first electromagnetic waves w1 may decrease. The extinction coefficient of the first electromagnetic waves w1 may be inversely proportional to the frequency.

The extinction coefficient of the first electromagnetic waves w1 may have a negative first derivative with respect to the frequency. The extinction coefficient of the first electromagnetic waves w1 may have a positive second derivative with respect to the frequency.

The first electromagnetic waves w1 may have a first extinction coefficient e1 at the first frequency f1. The first electromagnetic waves w1 may have a first slope s1 which is an instantaneous slope with respect to the first extinction coefficient e1 at the first frequency f1.

The first electromagnetic waves w1 may have a second extinction coefficient e2 at the second frequency f2. The first electromagnetic waves w1 may have a second slope s2 which is an instantaneous slope with respect to the second extinction coefficient e2 at the second frequency f2.

When the first frequency f1 is lower than the second frequency f2, an absolute value of the first slope s1 may be greater than an absolute value of the second slope s2. The extinction coefficient of the first electromagnetic waves w1 may be inversely proportional to the frequency, and a decrease rate thereof decreases in proportion to the frequency.

The extinction coefficient calculation unit 153 may calculate the extinction coefficient of each of the first electromagnetic waves w1 and the second electromagnetic waves w2 at a specific frequency. The thickness calculation unit 160 may calculate the thickness of the specimen 10 on the basis of a value calculated by the extinction coefficient calculation unit 153 and the function prestored in the function storage unit 140.

The extinction coefficient-thickness function prestored in the function storage unit 140 may have an increasing graph. At a specific frequency, the extinction coefficient may be proportional to the thickness of the specimen. At the specific frequency, as the extinction coefficient increases, the thickness of the specimen may increase.

A result value calculated by the extinction coefficient calculation unit 153 and a result value calculated by the thickness calculation unit 160 may be transmitted to the function storage unit 140. The function storage unit 140 may correct the extinction coefficient-thickness function on the basis of results received from the extinction coefficient calculation unit 153 and the thickness calculation unit 160.

1. A thickness measuring device comprising:
an emission unit emitting an electromagnetic wave toward a specimen;
a reception unit receiving an electromagnetic wave output from a direction in which the specimen is positioned; and
a control unit calculating a thickness of the specimen by receiving a signal from the reception unit;
wherein when the specimen has a first thickness, the reception unit receives a first electromagnetic wave, and when the specimen has a second thickness, the reception unit receives a second electromagnetic wave,
wherein the first electromagnetic wave has a first peak value at a first time point, and the second electromagnetic wave has a second peak value at a second time point, and
wherein when the first thickness is greater than the second thickness, the first peak value is smaller than the second peak value.

2. Device according to claim 1, wherein the first time point is a time point which is faster than the second time point.

3. Device according to claim 1, wherein the first thickness is in inversely proportional to the first time point and the first peak value.

4. Device according to claim 1, wherein the control unit includes a complex relative refractive index calculation unit calculating complex relative refractive index of the specimen using FFT (Fast Fourier Transform) algorithm to the first electromagnetic wave and the second electromagnetic wave and an extinction coefficient calculation unit calculating extinction coefficient of the specimen.

5. Device according to claim 4, wherein the control unit includes a function storage unit for storing functions for the complex relative refractive index and extinction coefficient with respect to the thickness of the specimen in the frequency domain in advance, and a thickness calculation unit for calculating a thickness of the specimen based on a value calculated by the complex relative refractive index calculation unit and the extinction coefficient calculation unit and a value stored at the function storage unit.

6. Device according to claim 5, wherein the control unit includes a data storage unit for storing a data output from the thickness calculation unit, and
wherein the data stored in the data storage unit is transferred to the function storage unit so that a function stored in the function storage unit can be modified.

7. Device according to claim 4, wherein when the first thickness is greater than the second thickness, the complex relative refractive index of the first electromagnetic wave is smaller than the complex relative refractive index of the second electromagnetic wave.

8. Device according to claim 4, wherein when the first thickness is greater than the second thickness, the extinction coefficient of the first electromagnetic wave is greater than the extinction coefficient of the second electromagnetic wave.

9. Device according to claim 4, wherein when the frequency increases, the complex relative refractive index of the first electromagnetic wave also increases.

10. Device according to claim 4, wherein the first electromagnetic wave has a first complex relative refractive index at a first frequency and a second complex relative refractive index at a second frequency,
wherein the first electromagnetic wave has a first slope with respect to the first complex relative refractive index at the first frequency, and a second slope with respect to the second complex relative refractive index at the second frequency, and
wherein when the first frequency is less than the second frequency, the first slope is greater than the second slope.

11. Device according to claim 4, wherein when the frequency increases, the extinction coefficient of the first electromagnetic wave decreases.

12. Device according to claim 4, wherein the first electromagnetic wave has a first extinction coefficient at a first frequency and a second extinction coefficient at a second frequency,
wherein the first electromagnetic wave has a first slope with respect to the first extinction coefficient at the first frequency, and a second slope with respect to the second extinction coefficient at the second frequency, and
wherein when the first frequency is less than the second frequency, an absolute value of the first slope is greater than an absolute value of the second slope.

13. Device according to claim 1, wherein the first electromagnetic wave and the second electromagnetic wave are terahertz waves.
